(19) United States
(12) Patent Application Publication
(10) Pub. No.: US 2008/0298535 A1
(43) Pub. Date: Dec. 4, 2008

(54) Circuit structure for timer counter and electrical device using the same

(76) Inventors: Wen-Ping Cheng, Yangmei Township (TW); Chien-Po Yang, Keelung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/010,452

(22) Filed: Jan. 25, 2008

(30) Foreign Application Priority Data
Jun. 1, 2007 (TW) 96119846

(51) Int. Cl. G01R 23/00

(52) U.S. Cl. 377/19

(57) ABSTRACT

A circuit structure for a timer counter counting the cycles of the pulse width of a digital signal corresponding to a clock signal is provided, wherein the signal type of the digital signal is Non-return to zero code. The timer counter circuit structure includes a first counter module and a second counter module. The first counter module receives the digital signal and the clock signal and counts the cycles of the pulse width of the digital signal corresponding to the clock signal while the logic of the digital signal is high. The second counter module receives the inverted digital signal and the clock signal and counts the cycles of pulse width of the inverted digital signal corresponding to the clock signal while the logic of the inverted digital signal is low.

### BACKGROUND OF THE INVENTION

1. Field of the Invention

The present invention relates to a timer counter circuit structure, and more particularly, to a timer circuit structure applicable for counting pulse width of digital signal as well as electrical device using the same.

2. Description of Related Art

In digital logic circuit, timer counter circuit structure is a kind of widely used circuit. Timer counter circuit is commonly used in decoding systems as a computing mechanism for counting the pulse width of digital signal. Referring to FIGS. 1, 2 and 3, in which FIG. 1 and FIG. 2 illustrate system architecture diagrams of a prior art timer counter circuit structure 1, FIG. 2 shows a circuit architecture of the counter module 10 of FIG. 1, while FIG. 3 shows a timing sequence diagram of digital signal R and inverted digital signal R′. The timer circuit structure depicted in FIGS. 1 and 2 is applicable for counting the pulse width of the digital signal R.

The signal type of the described digital signal R specifically refers to Non-return to zero (NRZ) code, which is formed by continuous logic high (logic value=1) signals and logic low (logic value=0) signals. In general, the signal type of infra-red remote-control signal is NRZ code. When the remote-control signal receiver receives the infra-red remote-control signal, it is necessary to decode the remote-control signal, so as to resolve the transferred message in the remote-control signal.

In order to perform continuous bi-phase counting upon digital signal R, as shown in FIG. 1, the timer counter circuit structure 1 includes a counter module 10 and two register modules 12, 14. The counter module 10 counts continuously the input clock signal Clk. At the same time, the counter module 10 also receives an enable signal En, wherein the enable signal En controls whether the counter module 10 performs counting or not based on whether the digital signal R is input externally. In case that no digital signal R is input externally, the enable signal En controls the counter module 10 to stop counting for saving power consumption; whereas if the digital signal R is input from outside, the enable signal En re-starts the counter module 10 to count.

In FIG. 2, the counter module 10 includes an AND gate 100, and a plurality of counters 102, 104, 106, 108 connected in series, wherein each counter 102, 104, 106, 108 is respectively formed by a flip-flop. The AND gate 100 simultaneously input the clock signal Clk and the enable signal En; hence, when the enable signal En is logic high, the clock signal Clk can input into the counters 102, 104, 106, 108 to be counted. The register modules 12, 14 are simultaneously coupled to the counter module 10, and these register modules 12, 14 are respectively formed by a plurality of latch registers, and individually controlled by the digital signal R and the inverted digital signal R′. When the digital signal R and the inverted digital signal R′ transit from logic high to logic low, counted values in each counter 102, 104, 106, 108 will be separately accessed into the register modules 12, 14.

Next, the operational mechanism of the timer counter circuit structure 1 will be further described in conjunction with the timing sequence of the digital signal R and the inverted digital signal R′ illustrated in FIG. 3. The counter module 10 constantly counts on the input clock signal Clk. When time T=t₀˜t₁, the counter module 10 continues its counting on the clock signal Clk; when T=t₁, the counter module 10 has equivalently counted cycles of pulse width T_{L0} of the digital signal corresponding to the clock signal Clk; at this moment, the inverted digital signal R′ transits from logic high to logic low, and the counter module 10 saves the counted value into the storage module 14, while the counters 102, 104, 106, 108 will be reset and re-count. When time T=t₁˜t₂, the counter module 10 continues its counting over the clock signal Clk; when T=t₂, the counter module 10 has equivalently counted cycles of pulse width T_{H1} of the digital signal corresponding to the clock signal Clk; at this moment, the digital signal R transits from logic high to logic low, and the value counted by the counter module 10 is accessed into the register module 12, while the counters 102, 104, 106, 108 will be reset and re-count. Similarly, when T=t₃, the counter module 10 has equivalently counted cycles of pulse width T_{L1} of the digital signal corresponding to the clock signal Clk; at this moment, the inverted digital signal R′ changes from logic high to logic low, and the value counted by the counter module 10 is accessed into the storage module 14, while the counters 102, 104, 106, 108 will be reset and re-count again. In brief, the register modules 12, 14 calculates respectively the logic high pulse width of the digital signal R and the inverted digital signal R′, so as to achieve the goal of continuous counting on the logic high and logic low signals of the digital signal R.

To implement the aforementioned prior art timer counter circuit structure 1, it requires inevitably a counter module 10 and two register modules 12, 14. Hence, when number of bits increases, the number of logic circuit components utilized therein will increase 3 times more along with the number of bits expands, which causes that chip area of the integrated circuit occupied by the timer counter circuit structure 1 and power consumption thereof will correspondingly increase. As the structure of digital circuit becomes more and more complicated, plus the requirement about miniaturization trend of integrated circuit chip, it is thus necessary to exploit design skills to further improve the timer counter circuit structure. In view of these issues, the inventors of the present invention proposed the present specification. The present invention is directed to the prior art timer counter circuit structure and presents an improvement solution thereof, so as to allow the timer counter circuit structure to better match the demands of integrated circuit design according to the proposition of the present invention.

### SUMMARY OF THE INVENTION

The object of the present invention is to provide a timer counter circuit structure and electrical device using the same, which calculates pulse width values of logic high and logic low of the digital signal by means of a first counter module and a second counter module, allowing simplification of logic circuits in the timer counter circuit structure.

The present invention discloses a timer counter circuit structure which is applicable for counting the cycles of a digital signal corresponding to a clock signal, wherein the signal type of the digital signal is Non-return to zero (NRZ) code. The timer counter circuit structure includes a first counter module and a second counter module. The first counter module receives the digital signal and the clock signal and counts the cycles of the pulse width of the digital signal corresponding to the clock signal while the logic of the digital signal is high. The second counter module receives the inverted digital signal and the clock signal and counts the cycles of pulse width of the inverted digital signal corresponding to the clock signal while the logic of the inverted digital signal is high.

The present invention additionally discloses an electronic device, which includes a receiving module, a clock generating module and a timer counter circuit structure. The timer counter circuit structure further includes a first counter module and a second counter module. The receiving module receives a preset signal, and converts the preset signal into a digital signal output, wherein the signal type of the digital signal is Non-return to zero code. The clock generating module generates a clock signal. The first counter module receives the digital signal and the clock signal and counts the cycles of the pulse width of the digital signal corresponding to the clock signal while the logic of the digital signal is high. The second counter module receives the inverted digital signal and the clock signal and counts the cycles of pulse width of the inverted digital signal corresponding to the clock signal while the logic of the inverted digital signal is high.

The above-mentioned summary as well as subsequent descriptions and drawings are both for further illustrating the measures, means and effects taken by the present invention to achieve the prescribed objectives. Other goals and advantages of the present invention will be explained in details in the following descriptions and drawings.

### BRIEF DESCRIPTION OF THE DRAWINGS

FIGS. 1 and 2 show system architecture diagrams of a prior are timer counter circuit structure, in which FIG. 2 shows a circuit architecture of the counter module in FIG. 1;

FIG. 3 is a timing sequence diagram of the digital signal R and the inverted digital signal R′ depicted in FIGS. 1 and 2;

FIG. 4 is a system architecture diagram of the timer counter circuit structure according to the present invention;

FIG. 5 is a system architecture diagram of an embodiment of the timer counter circuit structure according to the present invention; and

FIG. 6 is a system architecture diagram of the electronic device according to the present invention.

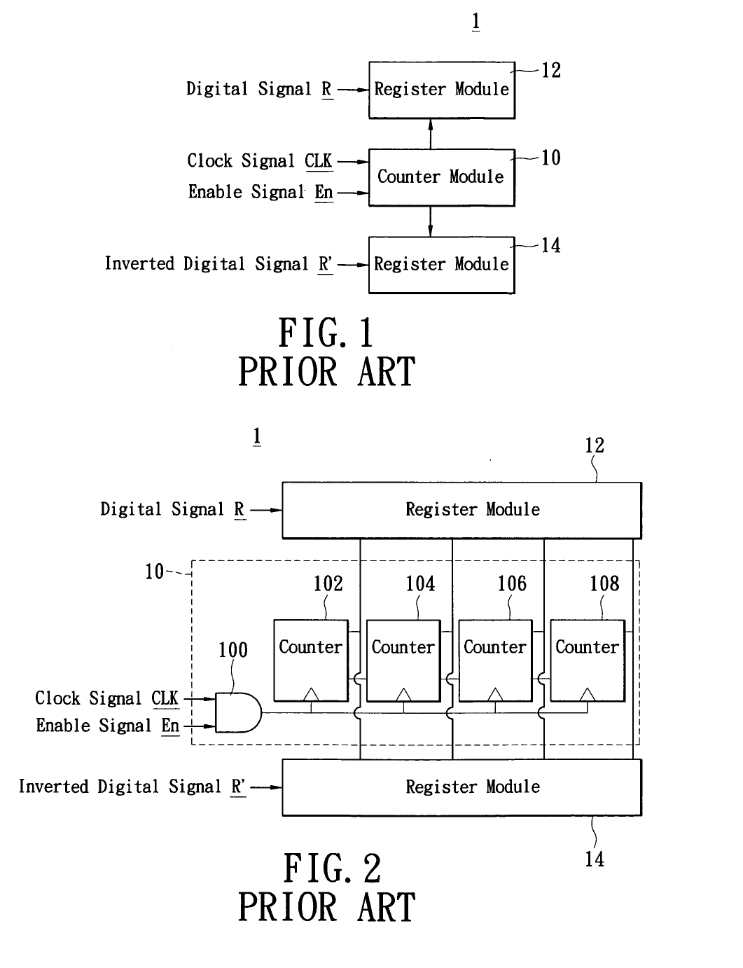

### DETAILED DESCRIPTION OF THE PREFERRED EMBODIMENTS

The present invention provides data registering function through timer counter formed by flip-flop, thus, in terms of continuous phase counting of signal, uses two sets of timer counters to calculate respectively pulse width of high level (logic value=1) and low level (logic value=0), so as to simplify prior art timer counter circuit structure.

First, referring to FIG. 4, therein a system architecture diagram of the timer counter circuit structure 2 according to the present invention is shown. The timer counter circuit structure 2 is applicable for counting cycle of pulse width of a digital signal R corresponding to a clock signal Clk, and the signal type of the said digit signal R is Non-return to zero (NRZ) code, which consists of continuous logic high (logic value=1) and logic low (logic value=0) signals.

As shown in FIG. 4, the timer counter circuit structure 2 includes a first counter module 20 and a second counter module 22. The first counter module 20 receives the digital signal R and the clock signal Clk and counts the cycles of the pulse width of the digital signal R corresponding to the clock signal Clk while the logic of the digital signal R is high. The second counter module 22 receives the inverted digital signal R′ and the clock signal Clk, in which the said inverted digital signal R′ is the inverted signal of the digital signal R, and counts the cycles of pulse width of the inverted digital signal R′ corresponding to the clock signal Clk while the logic of the inverted digital signal R′ is high. Therefore, in fact, the second counter module 22 is equivalently calculating the cycle of pulse width of the digital signal R corresponding to the clock signal Clk while being logic low.

In other word, the first counter module 20 and the second counter module 22 are respectively triggered ON to count by the positive edges (logic low to logic high) of the digital signal R and the inverted digital signal R′, also respectively triggered OFF to stop counting by the negative edges (logic high to logic low) of the digital signal R and the inverted digital signal R′. Therefore, the first counter module 20 counts the cycles of the pulse width of the digital signal R corresponding to the clock signal Clk while being logic high; contrarily, the second counter module 22 counts the cycles of the pulse width of the digital signal R corresponding to the clock signal Clk while being logic low, thus the digital signal R can be continuous counted by the first counter module 20 and the second counter module 22.

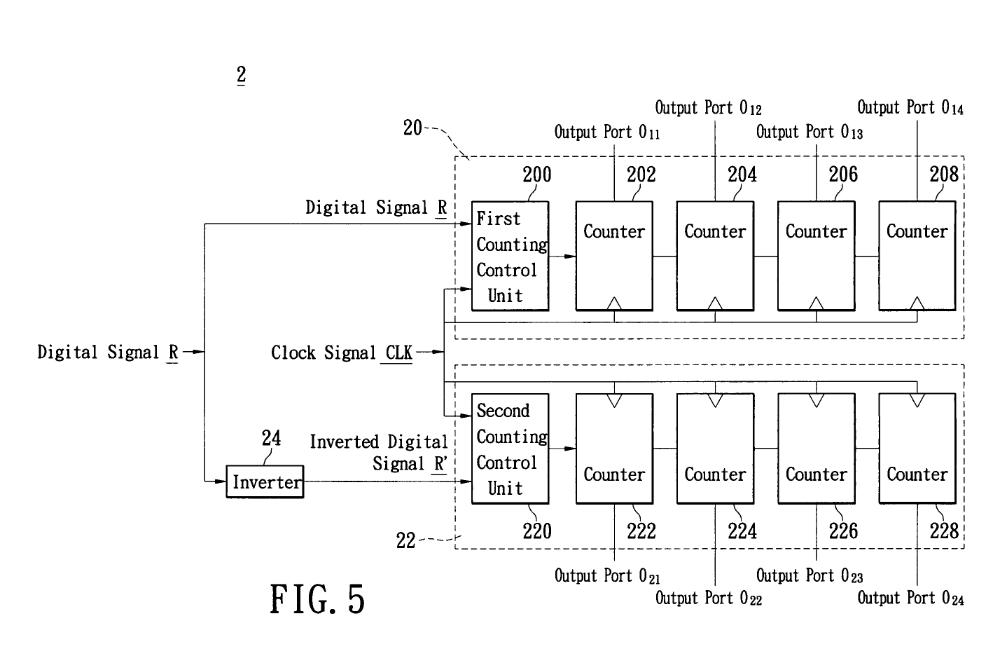

Subsequently, referring to FIG. 5, therein a system architecture diagram of an embodiment of the timer counter circuit structure 2 according to the present invention is shown. As illustrated in FIG. 5, the first counter module 20 includes a first counting control unit 200 and a plurality of counters 202, 204, 206, 208 connected in series, the second counter module 22 includes a second counting control unit 220 and a plurality of counters 222, 224, 226, 228 connected in series. It should be noted that, the number of counters the first counter module 20 and the second counter module 22 individually has, and connection method thereof, are configured in accordance with the number of bits, as shown in the diagram four (4) counters are used as an example, whereas this should not be interpreted as limiting the scope of the present invention.

The counters 202, 204, 206, 208, 222, 224, 226, 228 are respectively formed by flip-flops. The counters 202, 204, 206, 208 and the counters 222, 224, 226, 228 are respectively used to count the cycles of the pulse width of the digital signal R and the inverted digital signal R′ corresponding to the clock signal Clk while each being logic high, and output the counted values through output ports O₁₁, O₁₂, O₁₃, O₁₄ and output ports O₂₁, O₂₂, O₂₃, O₂₄.

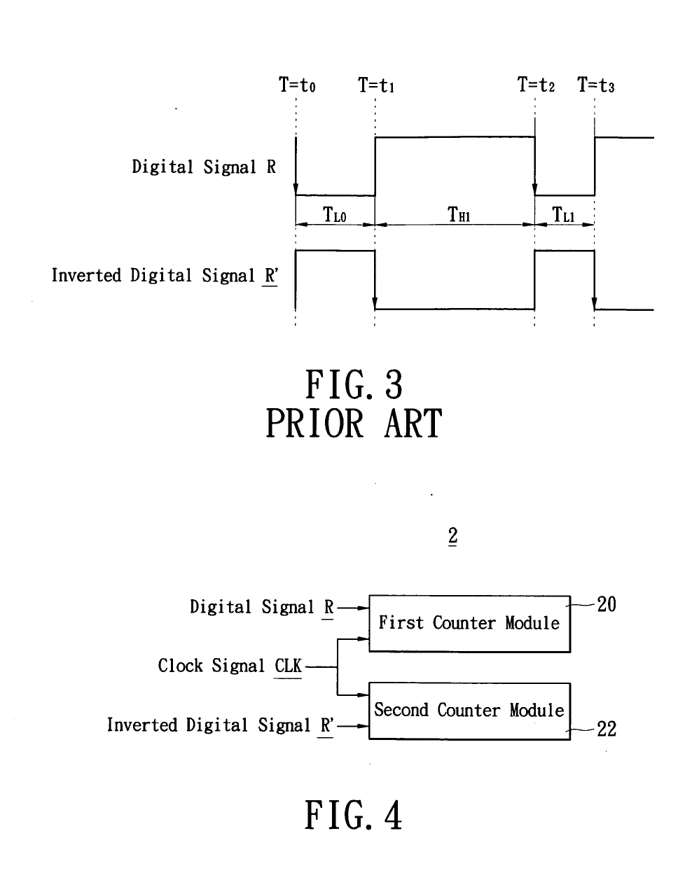

As shown in FIG. 5, the timer counter circuit structure 2 further includes an inverter 24, wherein the inverter 24 receives the digital signal R and inverts the logic value of the digital signal R to generate an inverted digital signal R′. The first counting control unit 200 receives the digital signal R and the clock signal Clk. When the digital signal R changes from logic low to logic high (as shown at time T=t₁, t₃ in FIG. 3), the first counting control unit 200 controls the clock signal Clk to start inputting to the counters 202, 204, 206, 208, hence each counter 202, 204, 206, 208 begins to count the cycle of the digital signal R corresponding to the clock signal Clk. When the digital signal R transits from logic high to logic low (as shown at time T=t₂ in FIG. 3), the first counting control unit 200 controls the clock signal Clk to stop inputting to the counters 202, 204, 206, 208, thus each counter 202, 204, 206, 208 stops counting. The counted values calculated by the counters 202, 204, 206, 208 are accessed through the output ports O₁₁, O₁₂, O₁₃, O₁₄. After this, the counters 202, 204, 206, 208 will be reset and counted values will be cleared, so as to perform counting again. Since the counted value resetting in the counters is well-known in the art, it will not be explained in details herein for the purpose of clarity.

The second counting control unit 220 receives the inversed digital signal R′ and the clock signal. When the inverted digital signal R′ transits from logic low to logic high (as shown at time T=t₀, t₂ in FIG. 3), the second counting control unit 220 controls the clock signal Clk to start inputting to the counters 222, 224, 226, 228, hence each counter 222, 224, 226, 228 begins to count the cycle of the inverted digital signal R′ corresponding to the clock signal Clk. When the inverted digital signal R′ transits from logic high to logic low (as shown at time T=t₁, t₃ in FIG. 3), the second counting control unit 220 controls the clock signal Clk to stop inputting to the counters 222, 224, 226, 228, thus each counter 222, 224, 226, 228 stops counting. The counted values calculated by the counters 222, 224, 226, 228 are accessed through the output ports O₂₁, O₂₂, O₂₃, O₂₄. After this, the counters 222, 224, 226, 228 will be reset and counted values will be cleared, so as to perform counting again.

The above-mentioned first counting control unit 200 and second counting control unit 220 each may include an AND gate circuit for respectively using the logical transitions of the digital signal R and the inverted digital signal R′ to control the output of the clock signal Clk.

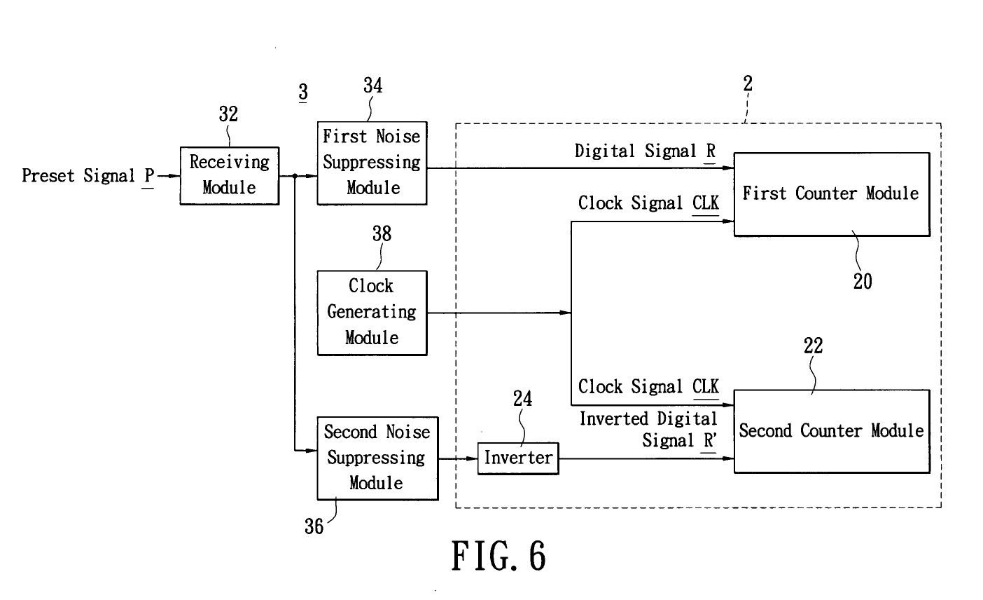

Furthermore, the above-mentioned timer counter circuit structure 2 can be applied in an electronic device. Referring to FIG. 6, therein a system architecture diagram of the electronic device 3 according to the present invention is shown. As illustrated in FIG. 6, the electronic device 3 includes a timer counter circuit structure 2, a receiving module 32, a first noise suppressing module 34, a second noise suppressing module 36 and a clock generating module 38. The timer counter circuit structure 2 is provided with a first counter module 20 and a second counter module 22.

The receiving module 32 receives a preset signal P, and converts the preset signal P into a digital signal R output. The signal type of the said digital signal R is NRZ code. The clock generating module 38 is a clock generating circuit which is used to generate a clock signal Clk. The first counter module 20 receives the digital signal R and the clock signal Clk and counts the cycles of the pulse width of the digital signal R corresponding to the clock signal Clk while the logic of the digital signal R is high. The second counter module 22 receives the inverted digital signal R′ and the clock signal Clk and counts the cycles of pulse width of the inverted digital signal R′ corresponding to the clock signal while the logic of the inverted digital signal R′ is high. Therefore, in fact, the second counter module 22 is equivalently calculating the cycle of pulse width of the digital signal R corresponding to the clock signal Clk while being logic low.

The above-mentioned electronic device 3 may be an infra-red remote-control signal receiver, and the preset signal P may be an infra-red remote-control signal emitted by a remote-controller. The above-mentioned receiving module 3f2 is formed by a photo-sensor and a photo-electrical converting circuit together, so as to convert the preset signal P into a digital signal, a type of electrical signal.

In FIG. 6, the first noise suppressing module 34 is installed between the receiving module 32 and the first counter module 20, the second noise suppressing module 36 is installed between the receiving module 32 and the second counter module 22. The first noise suppressing module 34 and the second noise suppressing module 36 are used as a mechanism to suppress the signal noise of the digital signal R, in order to avoid noise interference and to enhance signal stability. Besides, the first noise suppressing module 34 and the second noise suppressing module 36 may be respectively implemented by filtering circuits.

Additionally, the electronic device 3 further includes a processor (not shown), the said processor accesses the counted values calculated by the first counter module 20 and the second counter module 22 for further decoding the digital signal R, thus resolving the messages transferred by the digital signal R.

By way the aforementioned exemplary descriptions, it should be understood that the timer counter circuit structure according to the present invention employs a first counter module and a second counter module to separately count the cycles of the pulse width of the digital signal corresponding to the clock signal while being logic high and being logic low, so as to achieve the objective of continuous bi-phase counting upon digital signal. Compared with the prior art circuit structure composed of a counter module and two register modules, the timer counter circuit structure according to the present invention can be significantly less complicated, reducing the number of logic circuit components used in the circuit structure, further lessening the occupied area and required power consumption of the circuit structure, hence even more suitable for integrated circuit applications.

The above-mentioned illustrations present simply the detailed descriptions and drawings of the embodiments of the present invention, without any intention to restrict the scope of the present invention thereto. The entire range of the present invention should be based on the subsequent claims, and all changes, substitutions or modifications that persons skilled in the art can easily consider and fabricate fall within the scope of the present invention delineated by the claims.

What is claimed is:

1. A timer counter circuit structure, which is applicable for counting the cycles of the pulse width of a digital signal corresponding to a clock signal, wherein the signal type of the digital signal is Non-return to zero (NRZ) code, the timer counter circuit structure including:
a first counter module, which receives the digital signal and the clock signal and counts the digital signal's pulse width cycles corresponding to the clock signal while the digital signal logic is high; and
a second counter module, which receives the inverted digital signal and the clock signal and counts the inverted digital signal's pulse width cycles corresponding to the clock signal while the inverted digital signal logic is high.

2. The timer counter circuit structure according to claim 1, further includes an inverter which receives the digital signal to generate the inverted digital signal, and outputs the inverted digital signal to the second counter module.

3. The timer counter circuit structure according to claim 1, wherein the first counter module and the second counter module each includes a plurality of counters connected in series; wherein the counters of the first counter module count the digital signal's pulse width cycles corresponding to the clock signal while digital signal logic is high and the counters of the second counter module count the inverted digital signal's pulse width cycles corresponding to the clock signal while the inverted digital signal logic is high.

4. The timer counter circuit structure according to claim 3, wherein each of the plurality of counters is formed by a flip-flop.

5. The timer counter circuit structure according to claim 3, wherein the first counter module and the second counter module respectively include a first counting control unit and a second counting control unit; wherein the first counting control unit controls the clock signal to input to the first counters of the counter module when the digital signal logic is high, and the second counting control unit controls the clock signal to input to the counters of the second counter module when the inverted digital signal logic is high.

6. The timer counter circuit structure according to claim 5, wherein the first counting control unit receives the digital signal and the clock signal, and when the digital signal transits from logic low to logic high, the first counting control unit controls the clock signal and starts to input to first counter module counters, and first counter module counters start to count the digital signal cycle.

7. The timer counter circuit structure according to claim 6, wherein, when the digital signal transits from logic high to logic low, the first counting control unit controls the clock signal and stops inputting to first counter module counters, and first counter module counters stop counting.

8. The timer counter circuit structure according to claim 7, wherein, when first counter module counters stop counting, first counter module counters are reset for re-count.

9. The timer counter circuit structure according to claim 5, wherein the second counting control unit receives the inverted digital signal and the clock signal, and when the inverted digital signal transits from logic low to logic high, the second counting control unit controls the clock signal and starts to input to second counter module counters, and second counter module counters start to count the digital signal cycle.

10. The timer counter circuit structure according to claim 9, wherein, when the inverted digital signal transits from logic high to logic low, the second counting control unit controls the clock signal and stops inputting to second counter module counters, and second counter module counters stop counting.

11. The timer counter circuit structure according to claim 10, wherein, when second counter module counters stop counting, second counter module counters are reset for re-count.

12. The timer counter circuit structure according to claim 5, wherein the first counting control unit and the second counting control unit each includes an AND gate circuit.

13. An electrical device, which includes:
a receiving module, which receives a preset signal, and converts the preset signal into a digital signal output, wherein the signal type of the digital signal is Non-return to zero code;
a clock generating module, which generates a clock signal;
a timer counter circuit structure, which includes:
a first counter module, which receives the digital signal and the clock signal and counts the digital signal's pulse width cycle corresponding to the clock signal while the digital signal logic is high; and
a second counter module, which receives the inverted digital signal and the clock signal and counts the inverted digital signal's pulse width cycle corresponding to the clock signal while the inverted digital signal logic is high.

14. The electrical device according to claim 13, where the timer counter circuit structure further includes an inverter, the inverter receives the digital signal to generate inverted digital signal, and outputs the inverted digital signal to the second counter module.

15. The electrical device according to claim 13, wherein the first counter module and the second counter module each includes a plurality of counters connected in series; wherein first counter module counters count the digital signal's pulse cycles corresponding to the clock while digital signal logic is high, and second counter module counters count the inverted digital signal's pulse width cycles corresponding to the clock signal while inverted digital signal logic is high.

16. The electrical device according to claim 15, wherein each of the plurality of counters is formed by a flip-flop.

17. The electrical device according to claim 15, wherein the first counter module and the second counter module respectively includes a first counting control unit and a second counting control unit; wherein the first counting control unit controls the clock signal to input to first counter module counters when the digital signal logic is high, and the second counting control unit controls the clock signal to input to second counter module counters when the inverted digital signal logic is high.

18. The electrical device according to claim 17, wherein the first counting control unit receives the digital signal and the clock signal, and when the digital signal transits from logic low to logic high, the first counting control unit controls the clock signal and starts to input to first counter module counters, and first counter module counters start to count the digital signal cycle.

19. The electrical device according to claim 18, wherein, when the digital signal transits from logic high to logic low, the first counting control unit controls the clock signal and stops inputting to first counter module counters, and first counter module counters stop counting.

20. The electrical device according to claim 19, wherein, when first counter module counters stop counting, first counter module counters are reset for re-count.

21. The electrical device according to claim 17, wherein the second counting control unit receives the inverted digital signal and the clock signal, and when the inverted digital signal transits from logic low to logic high, the second counting control unit controls the clock signal and starts to input to second counter module counters, and second counter module counters start to count the digital signal cycle.

22. The electrical device according to claim 21, wherein, when the inverted digital signal transits from logic high to logic low, the second counting control unit controls the clock signal and stops inputting to second counter module counters, and second counter module counters stop counting.

23. The electrical device according to claim 22, wherein, when second counter module counters stop counting, second counter module counters are reset for re-count.

24. The electrical device according to claim 17, wherein the first counting control unit and the second counting control unit each includes an AND gate circuit.

25. The electrical device according to claim 13, further includes a first noise suppressing module and a second noise suppressing module, the first noise suppressing module is coupled between the receiving module and the first counter module, and the second noise suppressing module is coupled between the receiving module and the second counter module, wherein the first and second noise suppressing module are used to suppress digital signal noise.

26. The electrical device according to claim 13, which is an infra-red remote-control signal receiver.
